(19) United States
(12) Patent Application Publication
(10) Pub. No.: US 2024/0373594 A1
(43) Pub. Date: Nov. 7, 2024

(54) CASING FOR COMPUTERS AND RACK FOR COMPUTERS

(71) Applicant: SYSTEM INTELLIGENT CORP., Tokyo (JP)

(72) Inventor: Akihiro HASEGAWA, Tokyo (JP)

(21) Appl. No.: 18/310,568

(22) Filed: May 2, 2023

(51) Int. Cl. H05K 7/20

(52) U.S. Cl. CPC H05K 7/20436; H05K 7/20709

(57) ABSTRACT

A casing for computers for housing a plurality of compact computers includes a main body portion that houses the compact computers and a heat sink that is disposed in an outer surface side of one sidewall of the main body portion and is provided with a plurality of fins in a vertical direction. The main body portion includes a plurality of heat conduction plates that are in contact with radiator plates of the compact computers and are capable of conducting a heat, the heat conduction plates are disposed to be in contact with an inner surface side of the one sidewall of the main body portion, and a heat generated in the compact computers is released via the heat conduction plates and the heat sink.

### STATEMENT REGARDING PRIOR DISCLOSURES BY THE INVENTORS OR JOINT INVENTORS UNDER 37 C.F.R. 1.77 (b) (6)

Japanese Patent Application Publication No. 2023-2147A published Jan. 10, 2023 and Japanese Patent No. 7245870B2 published Mar. 24, 2023 (the publications) are “inventor-originated disclosures” within the exceptions defined in 35 U.S.C. 102 (b) (1). Copies of the publications are provided in a concurrently filed Information Disclosure Statement.

### BACKGROUND

### 1. Technical Field

The present invention relates to a casing for computers, and in particular, relates to a casing for computers for housing a plurality of computers.

### 2. Related Art

Recently, there are increased cases of operations of IT devices by using data centers. The use of data centers has an advantage of high degree of freedom in selecting hardware devices and networks to be used compared with the case where cloud services are used.

In a data center, many 19-inch racks are typically disposed and a user installs multiple servers in this rack to build a highly-functional cloud server in the data center, thus making it possible for the cloud server to stably function.

However, when the servers are installed in the 19-inch rack, usually one rack can only have tens of servers, thereby causing a problem of poor space efficiency.

A high-performance server is expensive, thereby also causing a problem of high cost in building the highly-functional cloud server.

### CITATION LIST

### Patent Literature

Patent Literature 1: Japanese Registered Utility Model No. 3120049

Therefore, the inventor attempted to solve such problems by using multiple compact computers, such as Next Units of Computing (NUC), instead of a high-performance server.

Specifically, using such compact computers allows 200 or more of compact computers to be disposed in a 19-inch rack, and they can build a highly-functional cloud server. Since the NUC is relatively low in price, it is possible to build a more highly-functional cloud server at a lower price as a whole, compared with the case of using a high-performance server.

However, when the multiple compact computers are thus disposed in the 19-inch rack, the heat generated from the computers is difficult to be dissipated, and therefore, there has been a problem of reduced processing speed as the result of increased temperature of the computers.

In order to solve such a problem, the inventor has developed a casing for computers that can house a plurality of compact computers and has a structure easily dissipating the heat generated from the computers.

The inventor also made it possible that, when a plurality of these casings for computers are disposed in the 19-inch rack, the heat generated from these computers are more easily released.

Specifically, the casing for computers includes a heat sink on which a plurality of fins are formed, and a heat conduction plate for each compact computer, thereby making it possible to dissipate the heat from radiator plates of the compact computers via the heat conduction plates and the heat sink.

Mounting a plurality of such casings for computers in the rack for computers with each of projecting portions and depressed portions of the plurality of fins on the heat sink aligning in a vertical direction ensures more effectively releasing the heat from the computers using a blown-air inside a data center.

When the heat is released from the computers, usually, an electric cooling system, such as an electric fan, is installed in the casing to dissipate the heat inside the casing. However, the electric fan has a short service life, and in the case where it is broken, the heat release from the compact computers is no longer possible, which has caused troubles.

Therefore, the present invention has made it possible to release the heat from the compact computers via the heat conduction plates and the heat sink without disposing the electric cooling system, such as the electric fan, in the casing for computers as described above. By mounting such a casing for computers in the rack as described above, it has also been made possible to more effectively release the heat.

Furthermore, the present invention with such a configuration also ensures eliminating the power consumption by the electric cooling system.

Here, Patent Literature 1 discloses a personal computer case including a heat dissipation unit on a top surface panel or a bottom surface panel.

However, this personal computer case cannot internally house a plurality of compact computers or does not have a structure easily dissipating the heat released from the plurality of computers.

The present invention has been made in consideration of the above-described circumstances, and an object of the present invention is to provide a casing for computers that easily dissipates a heat generated from a plurality of compact computers, a rack for computers, and a method for using the casing for computers.

### SUMMARY

In order to achieve the above-described object, there is provided a casing for computers for housing a plurality of housings having a computer function. The casing for computers has a configuration in which the casing for computers includes a main body portion that houses the housings and a heat sink that is disposed in an outer surface side of one sidewall of the main body portion and is provided with a plurality of fins in a vertical direction. The main body portion includes a plurality of heat conduction plates that are in contact with radiator plates of the housings and are capable of conducting a heat, the heat conduction plates are disposed to be in contact with an inner surface side of the one sidewall of the main body portion, and a heat generated in the housings is released via the heat conduction plates and the heat sink.

The casing for computers of the present invention preferably has a configuration in which another sidewall of the main body portion is made up of a rack mounting wall portion for securing the casing for computers to a rack for computers.

The casing for computers of the present invention preferably has a configuration in which the housing is disposed to be housed in the main body portion, and the housing is secured to the heat conduction plate such that the radiator plate of the housing is in contact with the heat conduction plate.

The casing for computers of the present invention preferably has a configuration in which the housing is a Next Unit of Computing (NUC) and two to eight heat conduction plates are disposed in the main body portion.

The casing for computers of the present invention preferably has a configuration in which no electric cooling system is disposed.

Furthermore, a rack for computers of the present invention is a rack for computers in which the above-described casing for computers is housed and has a configuration in which a plurality of the casings for computers are mounted on the rack for computers such that each of projecting portions and depressed portions of the plurality of fins in the heat sinks aligns in a vertical direction.

The rack for computers of the present invention preferably has a configuration in which the plurality of casings for computers are further mounted in the vertical direction such that the heat sinks face one another.

The rack for computers of the present invention preferably has a configuration in which the rack for computers is a 19-inch rack, and 2 to 14 of the plurality of casings for computers are mounted in the vertical direction on one side surface of the rack for computers, and another 2 to 14 of the plurality of casings for computers are mounted in the vertical direction on an opposite side surface of the one side surface of the rack for computers such that the heat sinks face one another.

### Advantageous Effects of Invention

The present invention ensures providing a casing for computers that easily dissipates a heat generated from a plurality of compact computers, a rack for computers, and a method for using the casing for computers.

### BRIEF DESCRIPTION OF DRAWINGS

FIG. 1 is a perspective view illustrating a casing for computers according to an embodiment of the present invention;

FIG. 2 is a front view illustrating the casing for computers according to the embodiment of the present invention;

FIG. 3 is a plan view illustrating the casing for computers according to the embodiment of the present invention;

FIG. 4 is a right side view illustrating the casing for computers according to the embodiment of the present invention;

FIG. 5 is a back view illustrating the casing for computers according to the embodiment of the present invention;

FIG. 6 is a bottom view illustrating the casing for computers according to the embodiment of the present invention;

FIG. 7 is a perspective view illustrating a compact computer housed in the casing for computers according to the embodiment of the present invention;

FIG. 8 is an explanatory view illustrating mounting of the compact computer on a heat conduction plate in the casing for computers according to the embodiment of the present invention;

FIG. 9 is a perspective view illustrating a state where the compact computers are housed in the casing for computers according to the embodiment of the present invention;

FIG. 10 is a plan view illustrating a state where the compact computers are housed in the casing for computers according to the embodiment of the present invention;

FIG. 11 is a right side view illustrating a state where the compact computer is housed in the casing for computers according to the embodiment of the present invention;

FIG. 12 is a front view illustrating a rack for computers housing the casings for computers according to the embodiment of the present invention;

FIG. 13 is a back view illustrating the rack for computers housing the casings for computers according to the embodiment of the present invention;

FIG. 14 is a side view illustrating the rack for computers housing the casings for computers according to the embodiment of the present invention;

FIG. 15 is a drawing illustrating a graph of an experimental result of Example 1 executed for confirming an effect of the casing for computers according to the embodiment of the present invention; and

FIG. 16 is a drawing illustrating data of an experimental result of Example 2 executed for confirming an effect of the casing for computers according to the embodiment of the present invention.

### DETAILED DESCRIPTION

The following describes an embodiment of a casing for computers, a rack for computers, and a method for using the casing for computers of the present invention in detail. However, the present invention is not limited to the specific contents in the embodiment and Examples below.

### Casing For Computers

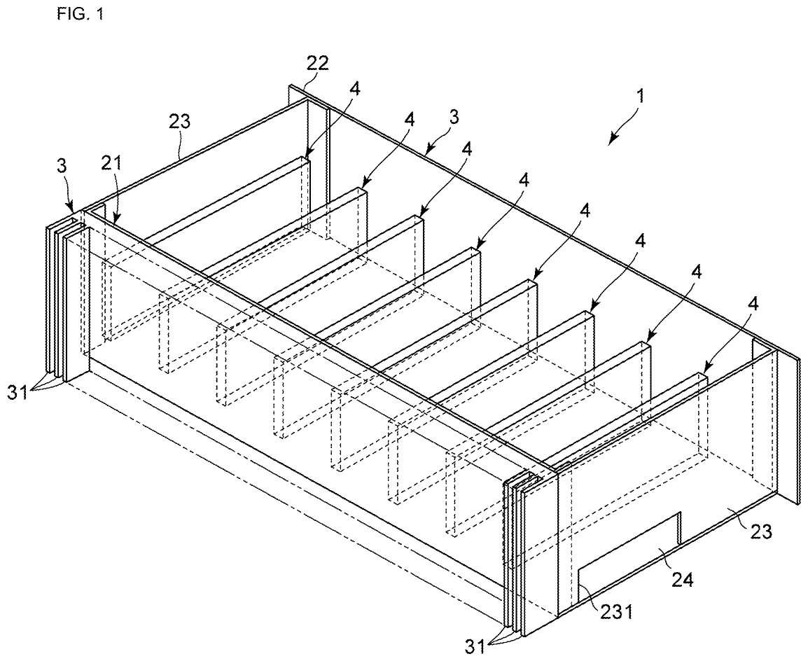

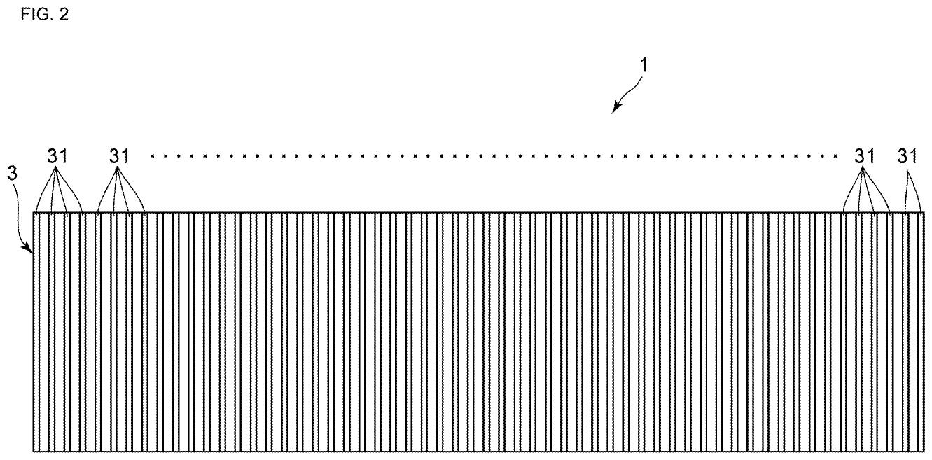

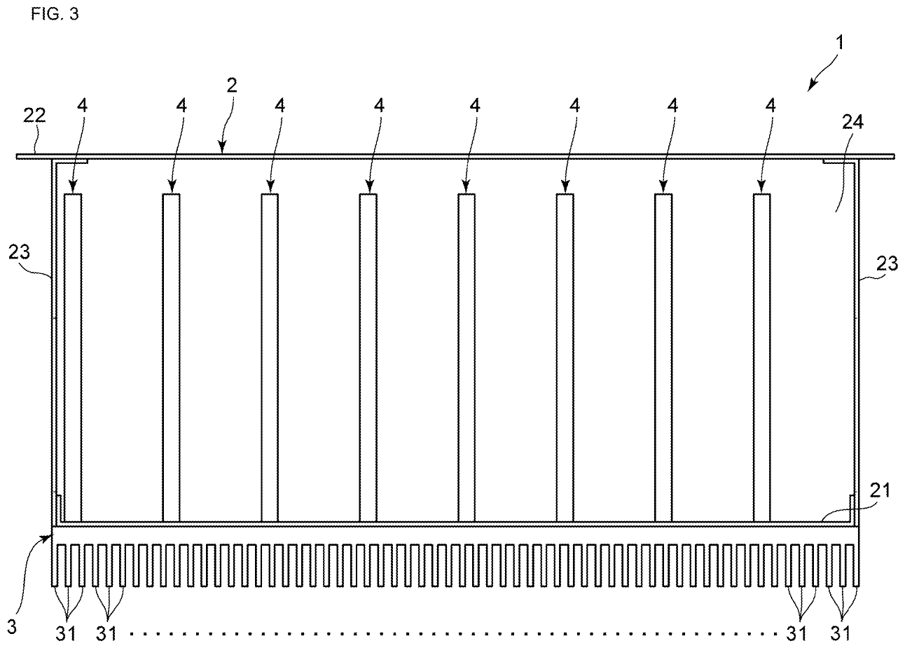

First, a casing for computers of this embodiment will be described with reference to FIG. 1 to FIG. 6. FIG. 1 to FIG. 6 are a perspective view, a front view, a plan view, a right side view, a back view, and a bottom view, respectively, of the casing for computers of this embodiment. Note that a left side view is omitted as it is symmetrical to the right side view.

As illustrated in FIG. 1 to FIG. 6, the casing for computers of this embodiment is a casing for computers 1 for housing a plurality of compact computers, such as Next Units of Computing (NUC), and includes a main body portion 2 that houses the compact computers and a heat sink 3 for cooling the compact computers housed in the main body portion 2.

The casing for computers 1 is preferred to be usable by being mounted on a rack, such as a 19-inch rack, and can have a size of, for example, approximately 48 cm×25 cm×13 cm.

The main body portion 2 includes a front wall portion 21 that secures and mounts the heat sink 3 on its outer surface side, a rack mounting wall portion 22 that secures and mounts the casing for computers 1 on the rack, such as the 19-inch rack, right and left sidewall portions 23 that connects these wall portions, and a bottom surface portion 24. While it is not illustrated, a removable top surface portion that covers a top surface side of the main body portion 2 may be disposed as well.

Note that, while in these drawings, the front wall portion 21 and the sidewall portions 23 are formed into a U shape and respectively secured to the sidewall portions 23 and the rack mounting wall portion 22, the specific shape and the securing method of the wall portion, the bottom surface portion, and the top surface portion are not limited to those, and the bottom surface portion may be formed into a U shape and secured, or all or parts may be integrally formed.

The main body portion 2 is preferred to be made of a material high in thermal conductivity, such as aluminum, copper, and a carbon material, such as carbon fiber, and in particular, the front wall portion 21 on which the heat sink 3 is secured is preferred to be constituted of a material having excellent thermal conductivity.

The front wall portion 21 of the main body portion 2 has its outer surface side on which the heat sink 3 is secured. Note that the heat sink 3 may be integrally formed with the front wall portion 21.

The heat sink 3 is a heat radiator and on which multiple fins 31 are formed in a vertical direction such that the heat accumulated in the main body portion 2 can be effectively released via the heat sink 3.

The heat sink 3 is preferred to be made of a material high in thermal conductivity, such as aluminum, copper, and a carbon material.

On the front wall portion 21 of the main body portion 2, a plurality of heat conduction plates 4 are disposed to be in contact with and secured to an inner surface side of the front wall portion 21.

The heat conduction plate 4 is preferred to be made of a material high in thermal conductivity, such as aluminum, copper, and a carbon material.

In the example of this embodiment, eight heat conduction plates 4 are secured to the front wall portion 21, and eight compact computers can be secured to these heat conduction plates 4.

Note that, in this embodiment, the number of the heat conduction plates 4 is not specifically limited but only necessary to be plural.

The securing method of the heat conduction plate 4 to the front wall portion 21 of the main body portion 2 is not specifically limited, and the heat conduction plate 4 can be secured to the front wall portion 21 with an adhesive having thermal conductivity or screws.

The securing method of the heat conduction plate 4 to the front wall portion 21 of the main body portion 2 is more preferably performed using the adhesive having thermal conductivity than using the screws from the aspect of the ease of processing the casing for computers 1. Furthermore, while it is not illustrated, the heat conduction plate 4 may be supported and secured by a support member.

The heat generated in the compact computers is released via the heat conduction plates 4 and the heat sink 3.

That is, the heat generated in the compact computers is transmitted to the heat conduction plates 4 from the compact computers and further transmitted to the heat sink 3 from the heat conduction plates 4 so as to be released to the outside of the casing for computers 1.

The casing for computers 1 of this embodiment has a configuration in which the heat generated in the compact computers is thus released via the heat conduction plates 4 and the heat sink 3, and therefore, compared with the configuration in which an electric cooling system, such as an electric fan, is installed in a casing to dissipate the heat inside the casing, it can avoid troubles caused by failures or the like in the electric cooling system. Since the electric cooling system is not disposed, the electric power consumption by the electric cooling system can also be eliminated.

Note that, in this embodiment, the casing for computers 1 is assumed to be one that can be mounted on the 19-inch rack, and the NUCs are assumed to be used for the compact computers.

However, when it is possible to use thinner compact computers for the compact computers, more heat conduction plates 4 can be disposed in the casing for computers 1 and the compact computers can be secured to the respective heat conduction plates 4.

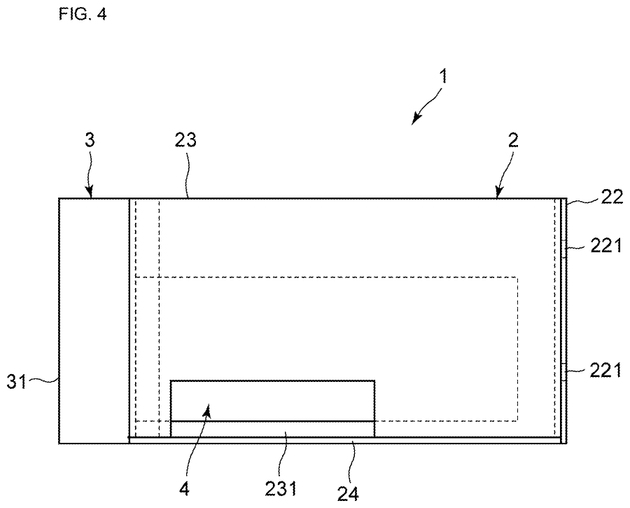

The sidewall portion 23 of the main body portion 2 is, as illustrated in FIG. 1 and FIG. 4, provided with a sidewall opening 231, and wirings, such as power supply cables and LAN cables, connected to the compact computers can be extracted to the outside from the casing for computers 1 through this sidewall opening 231.

The casing for computers 1 is thus provided with the sidewall openings 231 on the sidewall portions 23 and allows wiring through those so as to eliminate cables on the side of the front wall portion 21 of the main body portion 2. Such a configuration allows the plurality of heat conduction plates 4 to be disposed to be in contact with the front wall portion 21 of the main body portion 2.

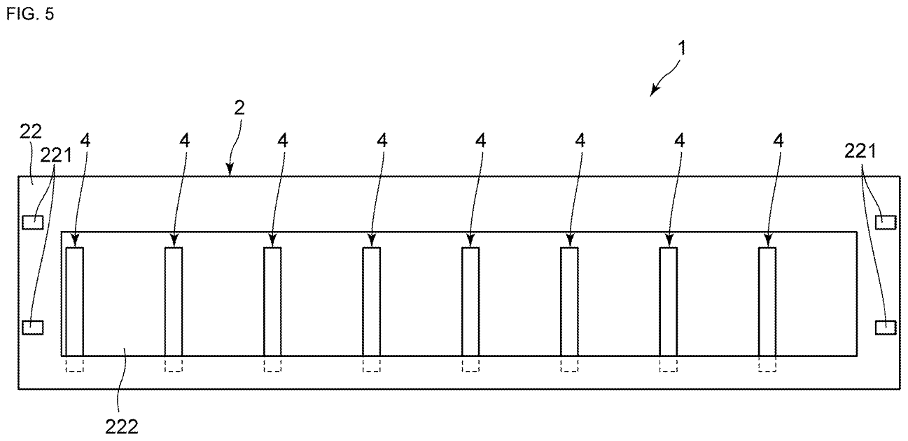

The rack mounting wall portion 22 of the main body portion 2 is, as illustrated in FIG. 5, provided with mounting holes 221 for mounting the casing for computers 1 to the rack and a mounting wall opening 222 to allow a direct operation as necessary, for example, a case where the compact computers housed in the casing for computers 1 are reset. Note that, in FIG. 1, the mounting holes 221 and the mounting wall opening 222 are omitted.

That is, the casing for computers 1 can be mounted on the 19-inch rack or the like with screws or the like via this mounting holes 221. Surely, the positions and the number of the mounting holes 221 are not specifically limited.

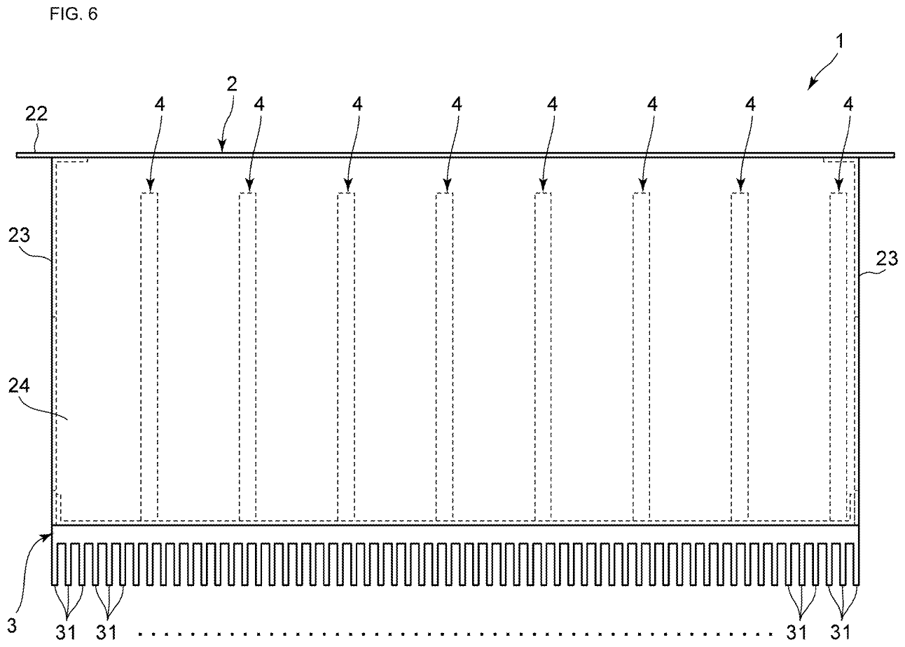

While the bottom surface portion 24 of the main body portion 2 covers the entire bottom surface of the main body portion 2 as illustrated in FIG. 6, an opening may be provided therein.

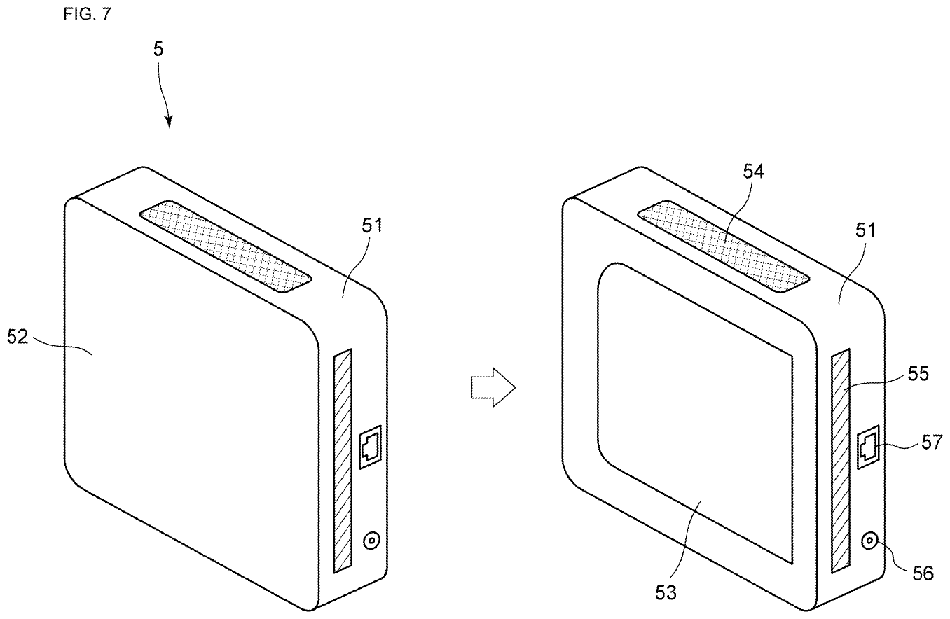

For the compact computers housed in the casing for computers 1 of this embodiment, for example, Next Units of Computing (NUC) 5 can be preferably used as illustrated in FIG. 7.

The NUC 5 is a compact computer with a size of approximately 10 cm×10 cm×2 cm, and when the casing for computers 1 of this embodiment can be mounted on the 19-inch rack, eight NUCs 5 can be housed in the casing for computers 1.

The NUC 5 includes a housing 51 and a lid 52, and internally includes a radiator plate 53, which is visible when the lid 52 is removed. Thus, the heat can be released from this radiator plate 53. The air is taken in from an air inlet 54 and is discharged from an exhaust outlet 55 to make a configuration of cooling the inside. Furthermore, the NUC 5 includes a power supply terminal 56 and a LAN terminal 57. While the NUC 5 may include any other configurations, such as a USB terminal and an HDMI output terminal, the description for them is omitted.

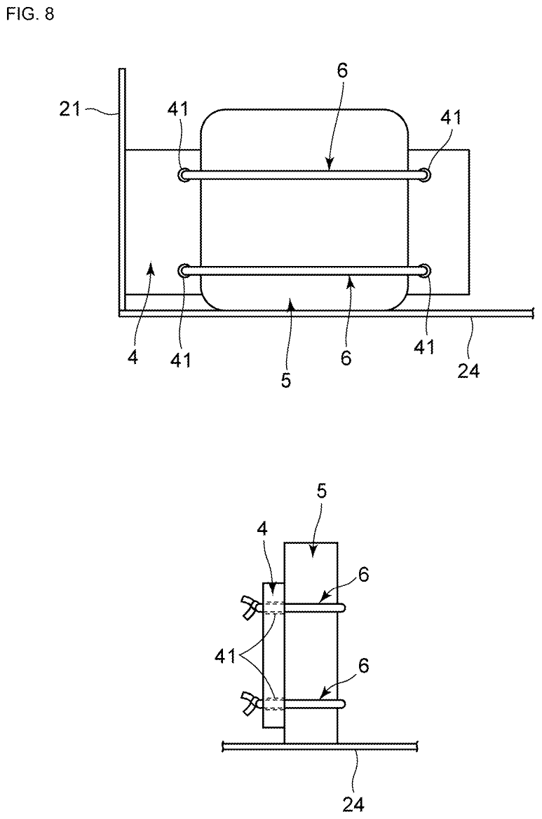

In the casing for computers 1 of this embodiment, the NUC 5 is, as illustrated in FIG. 8, preferred to be secured to the heat conduction plate 4 using heat-resistant rubbers 6.

At this time, it is preferred that the lid 52 is removed from the NUC 5 to expose the radiator plate 53, this radiator plate 53 is applied with an adhesive with thermal conductivity and then attached to the heat conduction plate 4, and the NUC 5 is secured to the heat conduction plate 4 using the heat-resistant rubbers 6.

The heat conduction plate 4 is provided with through-holes 41. The heat-resistant rubbers 6 are passed through these through-holes 41, thereby allowing the heat-resistant rubbers 6 to secure the NUC 5 to the heat conduction plate 4.

Thus securing the NUC 5 to the heat conduction plate 4 ensures releasing the heat generated from the NUC 5 to the outside of the casing for computers 1 via the heat conduction plate 4 and the heat sink 3 from the radiator plate 53.

Thus securing the NUC 5 to the heat conduction plate 4 using the heat-resistant rubbers 6 ensures easily mounting and removing the NUC 5 on/from the heat conduction plate 4.

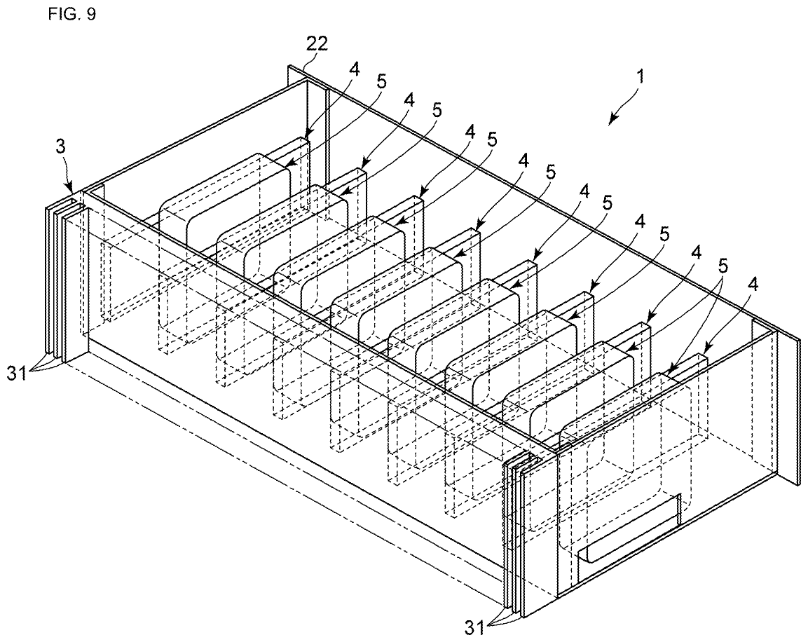

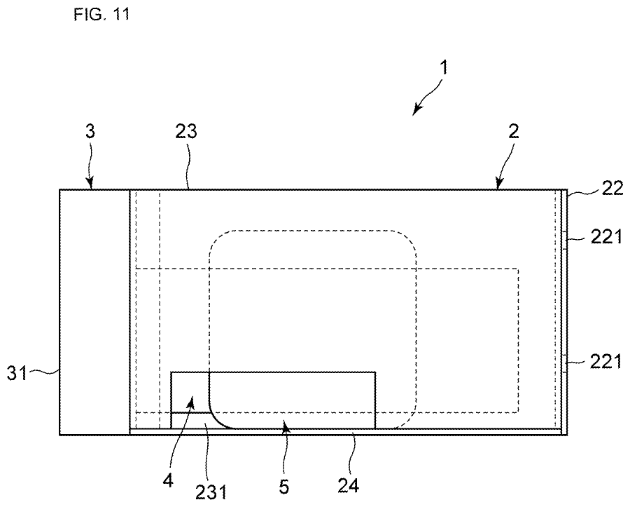

FIG. 9 to FIG. 11 illustrate the states where the casing for computers 1 of this embodiment houses the compact computers. FIG. 9 to FIG. 11 are a perspective view, a plan view, and a right side view, respectively, of the casing for computers 1 in which the compact computers are housed.

While these drawings illustrate the states where eight compact computers are housed in the casing for computers 1 of this embodiment, the number of the compact computers housed in the casing for computers 1 is not limited to this and one to seven compact computers may be housed.

The casing for computers 1 of this embodiment can include two to seven heat conduction plates 4 and have a configuration in which the compact computers are secured to the respective heat conduction plates 4, or can include nine or more heat conduction plates 4 and have a configuration in which the compact computers are secured to the respective heat conduction plates 4.

With such a casing for computers 1 of this embodiment, it is possible to house the plurality of compact computers and effectively release the heat generated from the compact computers via the heat conduction plates 4 and the heat sink 3.

Since the electric cooling system is not used for releasing the heat, occurrence of troubles based on failures of the electric cooling system can be avoided, thereby also making it possible to eliminate the power consumption by the electric cooling system.

### Rack For Computers

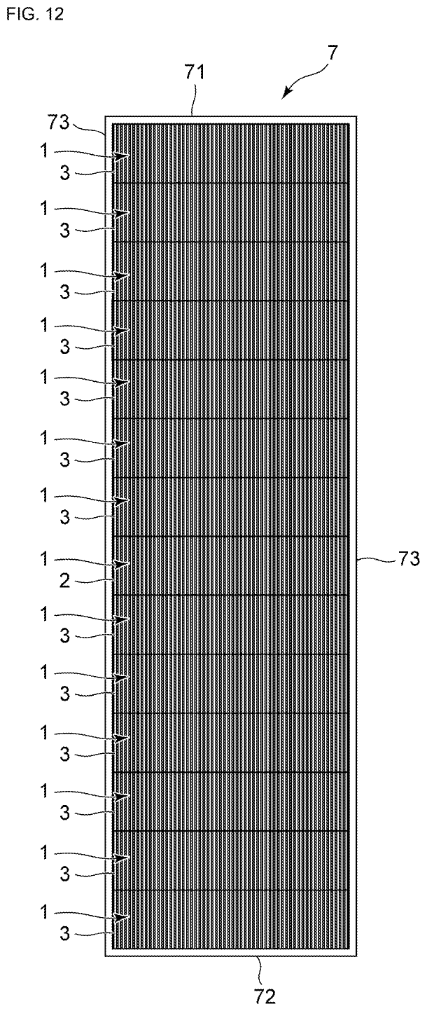

Next, the rack for computers of this embodiment will be described with reference to FIG. 12 to FIG. 14. FIG. 12 to FIG. 14 are a front view, a back view, and a side view, respectively, of the rack for computers in which the casings for computers according to the embodiment are housed.

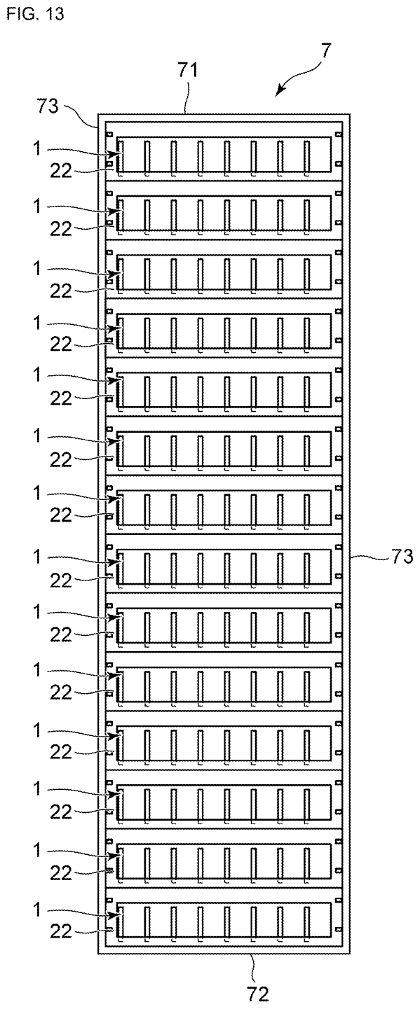

A rack for computers 7 of this embodiment has, as illustrated in FIG. 12 and FIG. 13, a configuration in which a plurality of the casings for computers 1 are mounted on the rack for computers 7 in a vertical direction via the rack mounting wall portions 22 such that each of the projecting portions and the depressed portions of the plurality of fins 31 in the heat sinks 3 align in the vertical direction.

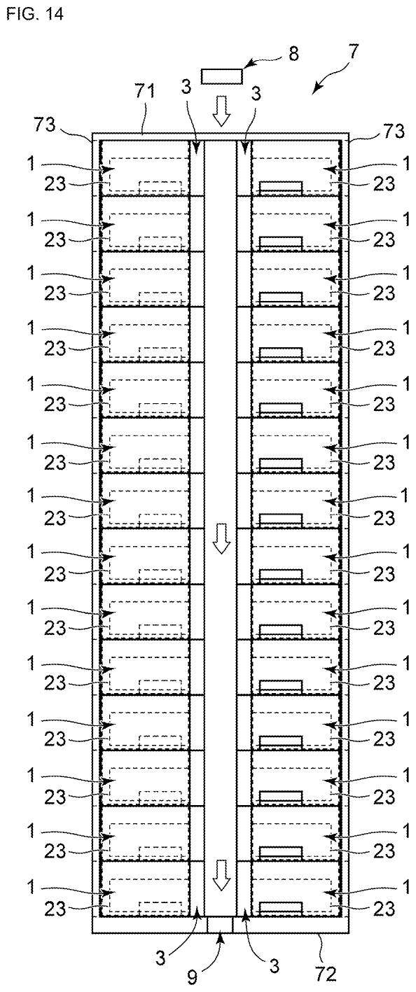

The rack for computers 7 of this embodiment has, as illustrated in FIG. 14, a configuration in which the plurality of casings for computers 1 are further mounted on the rack for computers 7 in the vertical direction via the rack mounting wall portions 22 such that the heat sinks 3 face one another.

In the examples in FIG. 12 to FIG. 14, the rack for computers 7 of this embodiment is configured by using the 19-inch rack, 14 casings for computers 1 are mounted in the vertical direction on one side surface of the rack for computers 7, and another 14 casings for computers 1 are mounted in the vertical direction on the opposite side surface of the above-described one side surface of the rack for computers 7 such that the heat sinks 3 face one another.

Accordingly, in the rack for computers 7 of this embodiment, a total of 224 (=8×14×2) compact computers are housed.

Note that, in the rack for computers 7 of this embodiment, 2 to 13 casings for computers 1 may be mounted in the vertical direction on one side surface of the rack for computers 7 and another 2 to 13 casings for computers 1 may be mounted in the vertical direction on the opposite side surface of the above-described one side surface of the rack for computers 7 such that the heat sinks 3 face one another.

Here, a data center typically includes many 19-inch racks, and a user installs computers on these racks to build a highly-functional cloud server in the data center, thus making it possible for the cloud server to stably function.

In the data center, air is sent vertically to the 19-inch racks to cool the computers.

Accordingly, the application of the rack for computers 7 of this embodiment in such a data center ensures vertically sending air at once to the heat sinks 3 in the casings for computers 1 arranged on both side surfaces in the rack for computers 7 by vertically sending air to the proximity of the center of the 19-inch rack.

Therefore, the heat generated from the compact computers housed within the casings for computers 1 can be effectively released via the heat conduction plates 4 and the heat sinks 3 without disposing the electric cooling system, such as the electric fan, within the casings for computers 1.

It is also conceivable that the top surface and the bottom surface of the casing for computers are provided with openings and the blown-air inside the data center is used to cool the compact computers in the casing.

However, when the plurality of casings for computers are mounted in the vertical direction, the air flow is restricted, and therefore, the compact computers cannot be appropriately cooled.

In contrast to this, the rack for computers 7 in which the casings for computers 1 of this embodiment are housed can effectively release the heat generated from the compact computers housed within the casings for computers 1 via the heat conduction plates 4 and the heat sinks 3, and in addition, allows the projecting portions and the depressed portions of the plurality of fins 31 in the heat sinks 3 to align in the vertical direction and the air to be vertically sent at once to these heat sinks 3.

Therefore, the rack for computers 7 of this embodiment ensures extremely effectively releasing the heat generated from the compact computers.

### Method for Using Casing for Computers

As illustrated in FIG. 14, a method for using the casing for computers of this embodiment is characterized by mounting the plurality of casings for computers 1 on the rack for computers 7 via the rack mounting wall portions 22 such that the projecting portions and the depressed portions of the plurality of fins 31 in the heat sinks 3 align in the vertical direction and further mounting the plurality of casings for computers 1 on the rack for computers 7 in the vertical direction via the rack mounting wall portions 22 such that the heat sinks 3 face one another, and vertically sending air to the space between the heat sinks 3 facing one another.

That is, as illustrated in the same drawing, a blower 8 is disposed, for example, on a ceiling in an upper center of the rack for computers 7 and an exhaust 9 is disposed, for example, on a floor in a lower center of the rack for computers 7.

Sending air from the blower 8 to the exhaust 9 ensures sending air to the heat sinks 3 of all the casings for computers 1 mounted on the rack for computers 7, and the heat generated from the compact computers housed in the casings for computers 1 can be released via the heat conduction plates 4 and the heat sinks 3.

As described above, with the casing for computers, the rack for computers, and the method for using the casing for computers of this embodiment, the heat generated from the plurality of compact computers can be effectively released.

### EXAMPLE

The following describes experiments executed for confirming effects of the casing for computers according to the embodiment of the present invention.

### Example 1

First, an experiment for confirming temperature changes of the heat conduction plate and the heat sink in the casing for computers of this embodiment was executed.

First, the casing for computers 1 illustrated in FIGS. 1 to 6 was fabricated. Aluminum members were used for the main body portion 2, the heat sink 3, and the heat conduction plates 4 of the casing for computers 1.

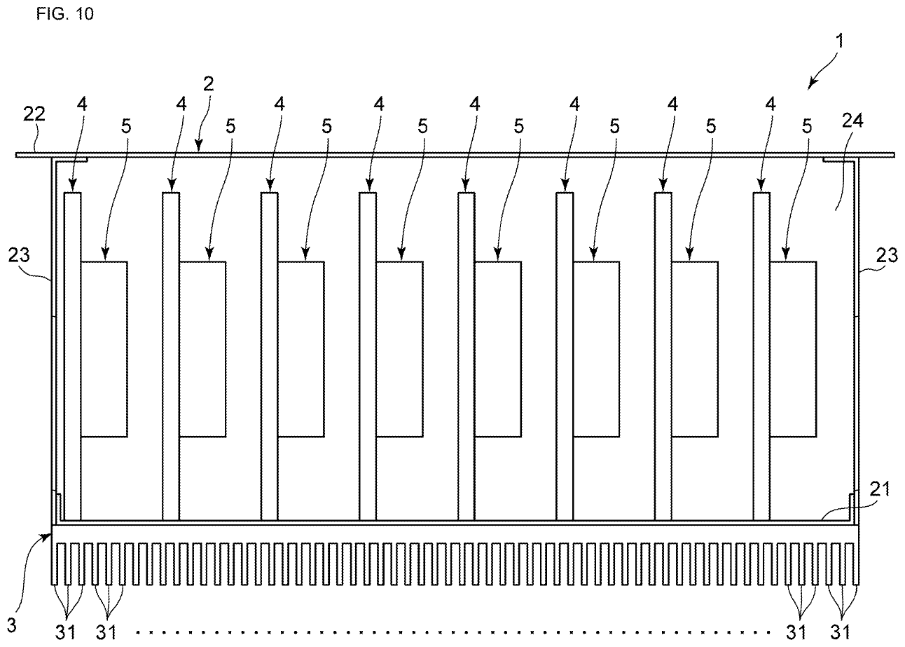

Eight NUCs (manufactured by Intel Corporation, model: BLKNUC7I7DNKE) were housed in this casing for computers as illustrated in FIG. 10, and were denoted as NUC (1) to NUC (8), respectively, from the left side viewing from the front.

At this time, the radiator plate 53 of the NUC was applied with an adhesive with thermal conductivity and was attached to the heat conduction plate 4. Each of the NUCs was secured to the heat conduction plate 4 using the heat-resistant rubbers 6.

Next, a thermometer 1 was secured on a right side surface of the heat conduction plate 4 to which the NUC (5) was attached and a thermometer 2 was secured on the heat sink 3 at the center in a vertical direction at a position corresponding to the heat conduction plate 4 to which the NUC (5) was attached.

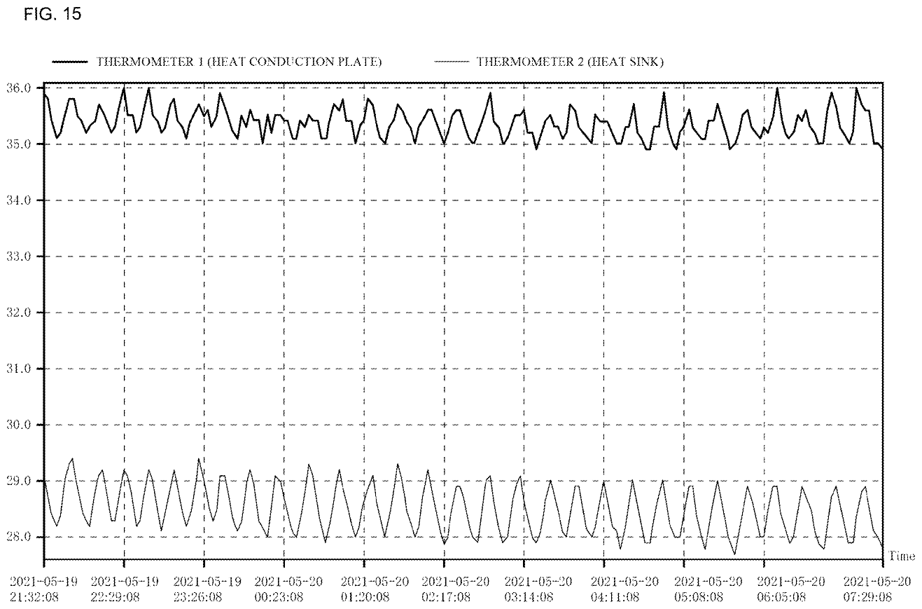

All the CPU cores in the eight NUCs had their processing set to 100% and temperatures of the heat conduction plate 4 and the heat sink 3 were measured every three minutes over ten hours from 9:30 pm to 7:30 am in the next day. The result is illustrated in the graph in FIG. 15.

As illustrated in the same drawing, the temperatures of the heat conduction plate 4 and the heat sink 3 of the casing for computers were maintained at mostly constant.

### Example 2

Along with the execution of Example 1, an experiment for confirming whether the temperature rise lowers the performance of the NUCs or not was executed by measuring temperatures and clock frequencies of the CPUs of the NUCs housed in the casing for computers of this embodiment.

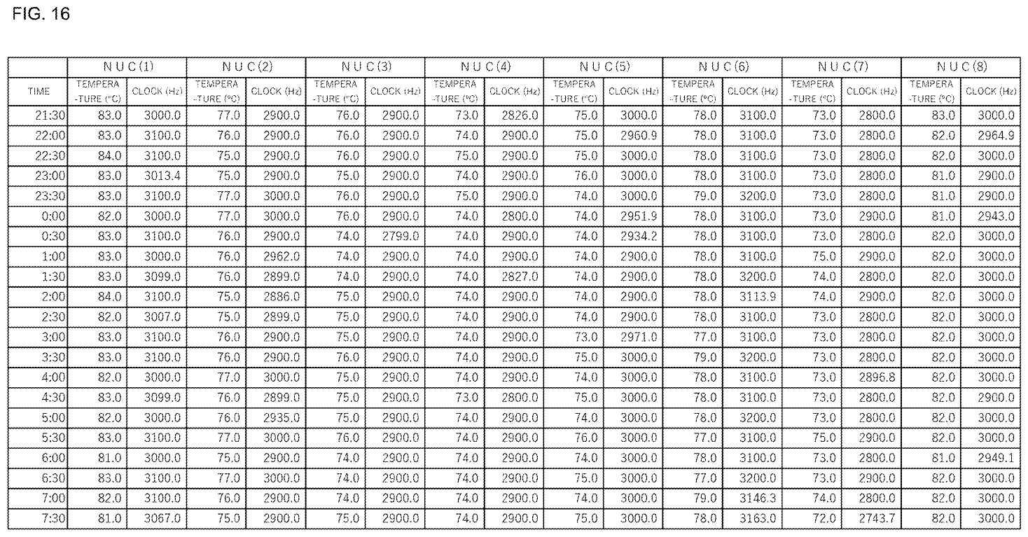

Specifically, all the CPU cores in the eight NUCs had their processing set to 100%, and temperatures were measured for each core of the CPUs and clock frequencies of the CPUs were measured using temperature measurement and CPU clock measurement equipped in the CPUs over ten hours from 9:30 pm to 7:30 am in the next day, and those pieces of data were recorded every 1 minute with a program via a driver. The average values of the CPU temperatures and the clock frequencies for each NUC for each 30 minutes obtained by aggregating the records are illustrated in FIG. 16.

As illustrated in the same drawing, it was found that the temperatures of all the NUCs were maintained almost constant over ten hours and the CPU clocks operated at approximately 3 GHz of the steady state. Thus, the experiment was executed using the casing for computers of this embodiment and with processing of all the CPU cores in the eight NUC being set to 100%, and the lowered processing speed by the temperature rise was not observed.

The present invention is not limited to the above-mentioned embodiment and it is needless to say that various kinds of changes are allowed within the scope of the present invention.

For example, appropriate changes, such as changing the shape and the position of the heat conduction plate in the casing for computers, are allowed.

### INDUSTRIAL APPLICABILITY

The present invention is preferably applicable for, for example, the case of installing many compact computers in a data center.

### REFERENCE SIGNS LIST

1 casing for computers
2 main body portion
21 front wall portion
22 rack mounting wall portion
221 mounting hole
222 mounting wall opening
23 sidewall portion
231 sidewall opening
24 bottom surface portion
3 heat sink
31 fin
4 heat conduction plate
41 through-hole
5 NUC (compact computer)
51 housing
52 lid
53 radiator plate
54 air inlet
55 exhaust outlet
56 power supply terminal
57 LAN terminal
6 heat-resistant rubber
7 rack for computers
71 top panel portion
72 bottom panel portion
73 mount support pillar
8 blower
9 exhaust

What is claimed is:

1. A casing for computers for housing a plurality of housings having a computer function, comprising:
a main body portion that houses the housings; and
a heat sink that is disposed in an outer surface side of one sidewall of the main body portion and is provided with a plurality of fins in a vertical direction, wherein
the main body portion includes a plurality of heat conduction plates that are in contact with radiator plates of the housings and are capable of conducting a heat, the heat conduction plates are disposed to be in contact with an inner surface side of the one sidewall of the main body portion, and
a heat generated in the housings is released via the heat conduction plates and the heat sink.

2. The casing for computers according to claim 1, wherein
another sidewall of the main body portion is made up of a rack mounting wall portion for securing the casing for computers to a rack for computers.

3. The casing for computers according to claim 1, wherein
the housing is disposed to be housed in the main body portion, and
the housing is secured to the heat conduction plate such that the radiator plate of the housing is in contact with the heat conduction plate.

4. The casing for computers according to claim 1, wherein
the housing is a Next Unit of Computing (NUC) and two to eight heat conduction plates are disposed in the main body portion.

5. The casing for computers according to claim 1, wherein no electric cooling system is disposed.

6. A rack for computers in which the casing for computers according to claim 1 is housed, wherein
a plurality of the casings for computers are mounted on the rack for computers such that each of projecting portions and depressed portions of the plurality of fins in the heat sinks aligns in a vertical direction.

7. The rack for computers according to claim 6, wherein
the plurality of casings for computers are further mounted in the vertical direction such that the heat sinks face one another.

8. The rack for computers according to claim 6, wherein
the rack for computers is a 19-inch rack, and
2 to 14 of the plurality of casings for computers are mounted in the vertical direction on one side surface of the rack for computers, and another 2 to 14 of the plurality of casings for computers are mounted in the vertical direction on an opposite side surface of the one side surface of the rack for computers such that the heat sinks face one another.
